(19) United States
(12) Patent Application Publication
(10) Pub. No.: US 2009/0115053 A1
(43) Pub. Date: May 7, 2009

(54) Semiconductor Package Thermal Performance Enhancement and Method

(76) Inventors: Sreenivasan K. Koduri, Allen, TX (US); Taylor R. Efland, Richardson, TX (US)

Correspondence Address: TEXAS INSTRUMENTS INCORPORATED, P O BOX 655474, M/S 3999, DALLAS, TX, 75265, US

(21) Appl. No.: 11/934,511

(22) Filed: Nov. 2, 2007

(51) Int. Cl. H01L 23/36; H01L 21/56

(52) U.S. Cl. 257/712; 438/122; 257/E23.101; 257/E21.506

(57) ABSTRACT

A semiconductor device package and related method are disclosed for providing a semiconductor device encapsulated in a protective package body. The device has an exposed surface to which a thermal compound is applied for improving a thermal path for the egress of heat from the device. Preferred embodiments are disclosed in which a removable cover is attached to the thermal compound for further improved protection during handling.

### TECHNICAL FIELD

The invention relates to electronic semiconductor devices and manufacturing. More particularly, the invention relates to microelectronic semiconductor package assemblies having features for promoting heat egress from the device for enhanced thermal performance and to methods for the manufacture of the same.

### BACKGROUND OF THE INVENTION

In conventional semiconductor device packages, a semiconductor device is mounted on a metallic leadframe with metallic connections and/or an adhesive material. Bond wires or contact pads on the device are coupled with contact pads incorporated into the surface of the substrate. An encapsulant material forms a protective covering over the device, bond wires, and some or all of the leadframe. Reductions in package size are constantly being pursued in the arts. With size reduction comes a high interconnection density, which can lead to a concentration of excess heat generated during operation of the circuitry. In general, the semiconductor device generates heat when operated and cools when inactive. Due to the changes in temperature, the package as a whole tends to thermally expand and contract. However, in many cases the thermal expansion behavior of the package, its internal components, e.g., device, leadframe, and underlying PCB, can differ, causing stresses to occur at the connecting joints, or within the layers of the package, or among the layers of the IC device itself.

Semiconductor packages known in the art tend to have limited inherent thermal dissipation capability. Various techniques are known for attempting to enhance the thermal performance of packages. It is known in the arts to include an internal heat spreader at the top or bottom layers of the device, or in the molded package. Incorporating heat spreaders into the device itself tends to be expensive. Whether included in the device or molded portion of the package, the heat spreader is typically a relatively large mass of metal placed in contact with the die pad, leadframe, or device for conducting heat away from the device. A typical assembly process for molded packages requires significant modifications in order to incorporate a built-in heat spreader. These efforts to improve heat egress from the device increase the cost of the package, and the additional internal heat spreader component increases package complexity and can be detrimental to long-term reliability.

For packages from which the dissipation of a significant amount of heat is of particular concern, it is a known practice to provide an exposed device or pad surface on the top or bottom of the package in order to dissipate heat directly into the surrounding air. A thermal pad may also be added to the exposed device or die pad surface in order to more rapidly conduct heat away from the device, or to increase the surface area available for heat dissipation. Sometimes an external heat sink is also attached to the surface of the package to conduct heat from a device or heat spreader. Such a heat sink usually includes one or more fins providing increased surface area for convective cooling, often for use with an electric fan. The effectiveness of an external thermal pad or heat sink, and the resulting package system, is largely dependent upon the efficient spreading of heat departing from the device for egress through the external pad or heat sink. The surfaces of the device, thermal pad, or heat sink are not perfectly smooth and flat. Since air is a very poor heat conductor, tiny air gaps between the adjacent surfaces can have a detrimental impact on heat transfer capabilities. Therefore, an interface material with a high thermal conductivity is often useful for filling these gaps to improve contact between the adjacent surfaces to improve heat conductivity. For this reason, it is known in the art to provide heat sinks with a thermal pad made from graphite or more expensive phase-change material, which melts to fill the fine gaps between the heat sink and the adjacent surface. Such pads are generally only suitable for a one-time installation, tend to be expensive, and are often not as effective as a thermal compound. Thermal compounds, also called “heat sink jelly”, “heat sink compound”, “thermal goo”, “silicon compound”, or “thermal grease” are sometimes used as interface material between adjacent components for enhanced heat transfer capability. Thermal compounds are typically applied directly to a thermal pad or heat sink placed in contact with a device, die pad, or package surface. A significant disadvantage of thermal compound is that it is quite messy to handle, sometimes contaminating nearby surfaces and tools, and therefore often not suitable for mass production processes. Thermal compounds can also tend to be highly electrically conductive as well thermally conductive. Thus, there is an additional hazard that any thermal compound that drips onto the board or adjacent electrical connections can cause a catastrophic failure of the assembly.

The present invention is directed to overcoming or reducing the effects of one or more of the problems noted. In addition to the problems identified above, thermal enhancements known in the arts for semiconductor device packages are faced with the additional problem of tending to increase the cost of the overall package. In general, to the extent the standard assembly processes are disrupted, process efficiency and yields decrease, and costs increase. Due to these and other problems, it would be useful and advantageous to provide semiconductor packages with improved heat dissipation capabilities, improved handling characteristics, and to provide manufacturing methods for using the same.

### SUMMARY OF THE INVENTION

In carrying out the principles of the present invention, in accordance with preferred embodiments thereof, the invention provides semiconductor package thermal performance enhancements and methods for providing package assemblies incorporating thermal performance enhancements.

According to one aspect of the invention, a preferred embodiment of a semiconductor device package system includes a semiconductor device encapsulated in a protective package body. The device has an unencapsulated surface, which is in turn surfaced with a thermal compound for conducting heat away from the device.

According to another aspect of the invention, an example of a preferred embodiment includes a semiconductor device package system having a semiconductor device affixed to a die pad with an exposed, unencapsulated surface. A thermal compound is affixed to the exposed die pad surface.

According to another aspect of the invention, in an exemplary method thereof, steps include providing a semiconductor device encapsulated in a protective package body. The device has an exposed, unencapsulated surface to which a thermal compound is applied.

According to another aspect of the invention, in an example of a preferred embodiment, a method for assembling a semiconductor device package includes steps for affixing a semiconductor device to a die pad, encapsulating the semiconductor die in a protective package body, and retaining an exposed, unencapsulated die pad surface. In further steps, a thermal compound is applied to the exposed die pad surface.

According to yet another aspect of the invention, preferred embodiments of methods of the invention may also include a step of attaching a removable cover to the thermal compound.

According to still another aspect of the invention, preferred embodiments of methods of the invention may also include a step of attaching a removable cover to the thermal compound and a further step of thereafter removing the removable cover to expose the thermal compound.

The invention provides advantages including but not limited to one or more of the following: enhanced heat egress from a packaged device, improved thermal performance of package assemblies, improved methods for implementing semiconductor device assemblies using thermally enhanced packages, improved handling, and reduced system costs. These and other features, advantages, and benefits of the present invention can be understood by one of ordinary skill in the arts upon careful consideration of the detailed description of representative embodiments of the invention in connection with the accompanying drawings.

### BRIEF DESCRIPTION OF THE DRAWINGS

The present invention will be more clearly understood from consideration of the following detailed description and drawings in which:

FIG. 1 is a cutaway side view representing a conceptual example of a semiconductor device package known in the art;

FIG. 2 is a cutaway side conceptual view of an example of a preferred embodiment of a semiconductor device package according to the invention;

FIG. 3 is a cutaway side view of an example of a preferred embodiment of a semiconductor device package according to the invention;

FIG. 4 is a cutaway side view of an example of another preferred embodiment of a semiconductor device package according to the invention;

FIG. 5 is a cutaway side view of another example of a preferred embodiment of a semiconductor device package according to the invention;

FIG. 6 is a cutaway side view of an alternative example of a preferred embodiment of a semiconductor device package according to the invention; and

FIG. 7 is a cutaway side view of another example of an alternative preferred embodiment of a leadless semiconductor device package according to the invention.

References in the detailed description correspond to like references in the various drawings unless otherwise noted. Descriptive and directional terms used in the written description such as first, second, top, bottom, upper, side, etc., refer to the drawings themselves as laid out on the paper and not to physical limitations of the invention unless specifically noted. The drawings are not to scale, and some features of embodiments shown and discussed are simplified or amplified for illustrating the principles, features, and advantages of the invention.

### DESCRIPTION OF PREFERRED EMBODIMENTS

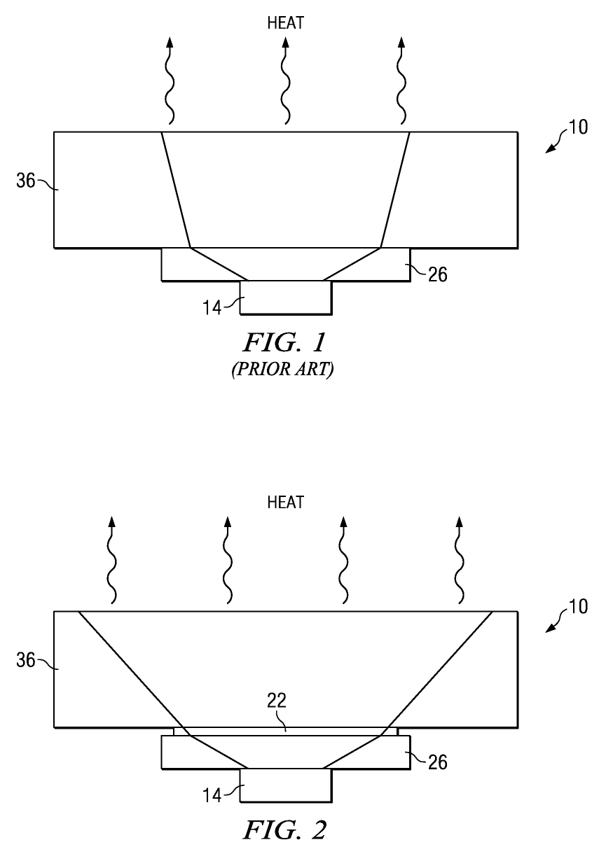

The invention provides high-performance semiconductor package systems and methods related to their manufacture. Preferably, thermal compound is positioned in contact with the surface of a semiconductor device or die pad. Suitable thermal compounds generally include a carrier such as a silicone paste with thermally conductive additives such as, for example, zinc or aluminum oxide or nitride, pulverized silver, or material having advantageous thermal conductivity. Using thermal compound with a high thermal conductivity improves the thermal path for conducting heat away from the surface of the semiconductor device or die pad, preferably to an external thermal pad or heat sink for further dissipation through convective cooling. FIGS. 1 (prior art) and 2 illustrate the advantageous effects of incorporating a thermally conductive compound into a semiconductor package 10. In the conceptual view of FIG. 1, a semiconductor device 14 is mounted in contact with a die pad 26, which is in turn mounted in contact with a heat sink 36 in order to facilitate departure of heat from the device 14. As shown in FIG. 2, the inclusion of a thermal compound 22, having high thermal conductivity, increases the transmission of heat through the die pad 26 and through the heat sink 36 where it may be dissipated. The thermal enhancements of the invention are provided while reducing the risk of contamination of nearby circuit components by errant thermal compound. Various embodiments of the invention may be implemented using available dispensable thermal compound materials such as semi-solid pastes or gels. The invention may be practiced with wirebonded or flip-chip type packages. The possible variations within the scope of the invention are numerous and cannot all be shown. Examples representative of alternative configurations of the invention are provided.

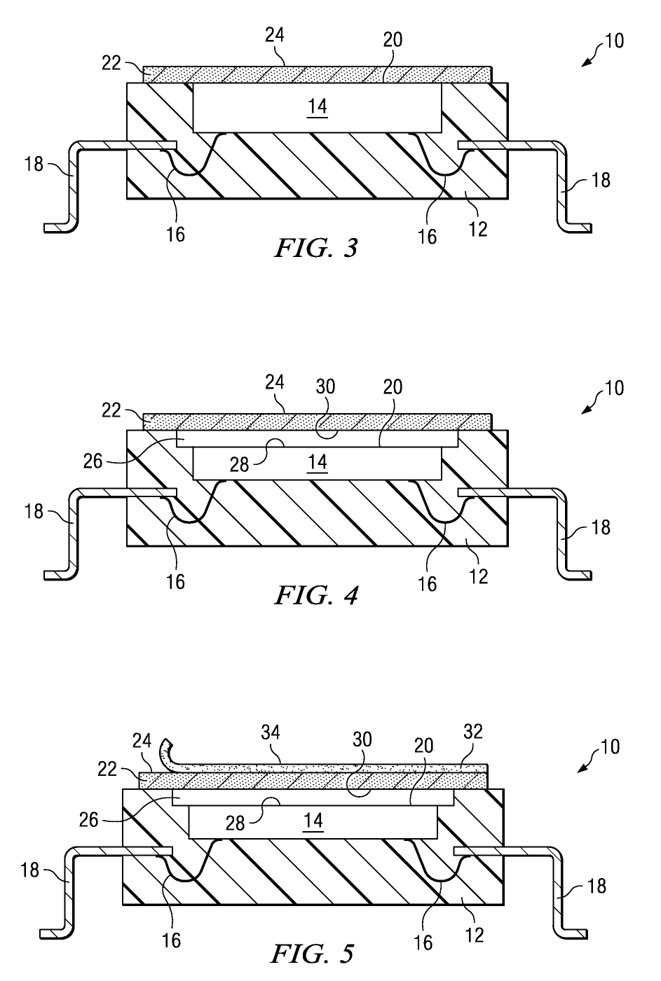

Referring primarily to FIG. 3, a semiconductor device package 10 is shown. A package body 12, typically molded plastic or epoxy resin, encases a semiconductor device 14. The package body 12 is preferably made from a rigid material. In general, electrical contacts provide connections from the device 14 in the interior of the package 10. In this example, wirebond connections 16 to external leads 18 are shown, although the invention may be practiced with leadless packages as well. As shown, a surface 20 of the device 14 is not encapsulated in the package body 12. Preferably, a highly conductive thermal compound 22 is provided on the package 10. The thermal compound 22 is in contact with the exposed device surface 20, providing a direct thermal path to the outer surface 24. Preferably, the thermal compound 22 provides an enlarged surface area 24 relative to the device surface 20 in order to enhance heat conduction away from the device 14. Preferably, thermal compound having high electrical conductivity incidental to high thermal conductivity may be used in implementing the invention due to the improved handling characteristics reducing contamination risks.

Now referring to FIG. 4, an alternative embodiment of a microelectronic semiconductor package assembly 10 with features for enhanced thermal performance according to the invention, is illustrated. As shown in this example, a die pad 26 may be encapsulated within the package body 12. One surface 28 of the die pad 26 adjoins the surface 20 of a die 14 mounted thereon. The opposing surface 30 of the die pad 26 is preferably devoid of mold compound. Thermal compound 22 is provided at the exposed die pad surface 30, providing a direct thermal path to the outer surface 24. Preferably, the die pad 26 provides an enlarged surface area 30 relative to the device surface 20, and the thermal compound 22 in turn provides an enlarged surface relative to the die pad surface 30, in order to enhance heat conduction away from the device 14.

The system and methods of the invention provide packages with pre-attached thermal compound for incorporation into larger electronic assemblies, advantageously reducing the handling problems associated with the application of thermal compound at the site of such larger assemblies. As shown in FIG. 5, a further example of a preferred embodiment of the invention includes a removable cover 32, preferably made from a thin flexible material such as a pliable film or tape. The removable cover 32 may be used to protect the thermal compound 22 from external contamination during handling, and to prevent items coming into contact with the package 10 from contamination by the thermal compound 22. The removable cover 32 may be made with an insulative material and/or include a reflective outer surface 34 to protect the package 10 and reduce the thermal effects of assembly processes such as reflow. Of course, the removable cover 32 may preferably be removed as required during component assembly, such as for the installation of an external heat sink on the package 10, for example.

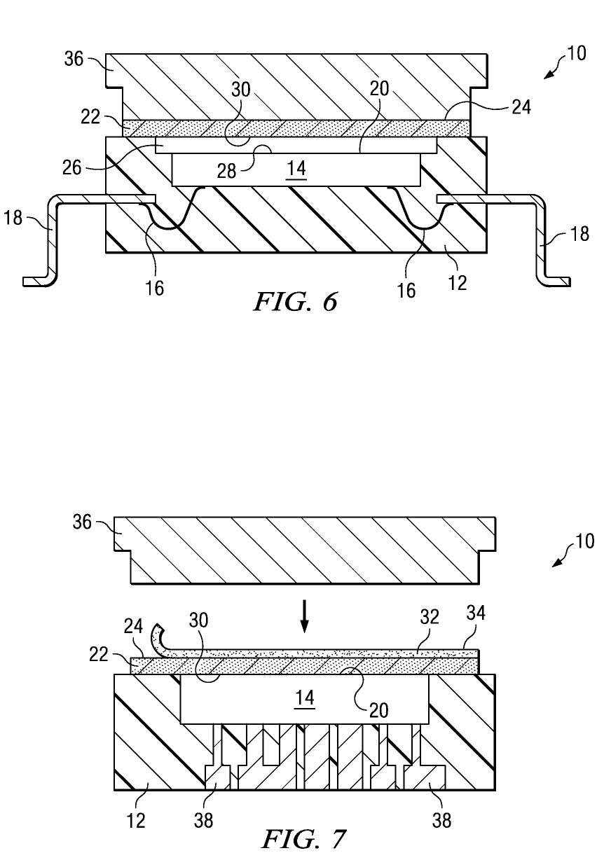

Now referring primarily to FIG. 6, a package system 10 is shown with the an external heat sink 36 attached, preferably using thermal compound 22 affixed thermal compound 22 provides an improved thermal path for the egress of heat from the device 14. The thermal compound 22 making the connection to the external heat sink 36 may be attached to the die pad 26, as shown in FIG. 4, or may alternatively interface directly with the device 14 in embodiments lacking an intervening die pad.

An example of an alternative embodiment of the invention is shown in the cutaway side view of FIG. 7. A leadless semiconductor device package 10 according to the invention is depicted with a removable cover 32 over a thermal compound 22 applied to a semiconductor device 14. An external heat sink 36 is shown being moved into position for attachment to the thermal compound 22 upon the detachment of the removable cover 32. The removable cover 32 protects the thermal compound 22 from contamination during handling and reflow. The presence of the removable cover 32 also protects nearby surfaces and tools from accidental contamination by thermal compound 22. Of course, the removable cover 32 is removed prior to placement of a heat sink 36. This embodiment of the invention is similar to those illustrated and described elsewhere herein, but differs in that the device 14, and thus the surrounding package 10, is configured for surface mountability, using ball grid array (BGA) electrical contacts 38, demonstrating that the invention is not limited to use with leaded packages. It should be appreciated that the invention may be practiced with the various package types found in the art.

The methods and systems of the invention provide one or more advantages, potentially including but not limited to; reductions in costs, increased system reliability, improved thermal performance, and more efficient assembly methods. While the invention has been described with reference to certain illustrative embodiments, those described herein are not intended to be construed in a limiting sense. For example, variations or combinations of steps or materials in the embodiments shown and described may be used in particular cases without departure from the invention. Various modifications and combinations of the illustrative embodiments as well as other advantages and embodiments of the invention will be apparent to persons skilled in the arts upon reference to the drawings, description, and claims.

We claim:

1. A semiconductor device package system comprising:
a semiconductor device encapsulated in a protective package body, the device having an exposed surface; and
a thermal compound applied to the exposed device surface.

2. The semiconductor device package system according to claim 1 further comprising a removable cover attached to the thermal compound.

3. The semiconductor device package system according to claim 1 further comprising external package leads.

4. The semiconductor device package system according to claim 1 further comprising surface-mountable external electrical connections, whereby a leadless package is provided.

5. The semiconductor device package system according to claim 1 further comprising a heat spreader attached to the thermal compound.

6. A semiconductor device package system comprising:
a semiconductor device affixed to a die pad, the semiconductor device encapsulated in a protective package body, and the die pad having an exposed surface; and
a thermal compound applied to the exposed die pad surface.

7. The semiconductor device package system according to claim 6 further comprising a removable cover attached to the thermal compound.

8. The semiconductor device package system according to claim 6 further comprising external package leads.

9. The semiconductor device package system according to claim 6 further comprising surface-mountable external electrical connections, whereby a leadless package is provided.

10. The semiconductor device package system according to claim 6 further comprising a heat spreader attached to the thermal compound.

11. A method for assembling a semiconductor device package comprising the steps of:
providing a semiconductor device encapsulated in a protective package body, the device having an exposed surface; and
applying a thermal compound to the exposed device surface.

12. The method according to claim 11 further comprising the step of attaching the semiconductor device bearing the thermal compound to a substrate.

13. The method according to claim 11 further comprising the step of attaching a removable cover to the thermal compound.

14. The method according to claim 11 further comprising the step of attaching a removable cover to the thermal compound; and
thereafter removing the removable cover to expose the thermal compound;
and subsequently attaching a heat spreader to the thermal compound.

15. A method of assembling a semiconductor device package comprising the steps of:
affixing a semiconductor device to a die pad, encapsulating the semiconductor device in a protective package body, and retaining an exposed die pad surface; and
applying a thermal compound to the exposed die pad surface.

16. The method according to claim 15 further comprising the step of attaching the semiconductor device and die pad bearing the thermal compound to a substrate.

17. The method according to claim 15 further comprising the step of attaching a removable cover to the thermal compound.

18. The method according to claim 15 further comprising the step of attaching a removable cover to the thermal compound; and
thereafter removing the removable cover to expose the thermal compound; and
subsequently attaching a heat spreader attached to the thermal compound.
